(19) United States
(12) Patent Application Publication
(10) Pub. No.: US 2003/0195860 A1
(43) Pub. Date: Oct. 16, 2003

(54) System and method for remotely measuring, monitoring and billing thermal energy usage

(76) Inventor: Jackson L. Ball, Atlanta, GA (US)

Correspondence Address: NIXON & VANDERHYE, PC, 1100 N GLEBE ROAD, 8TH FLOOR, ARLINGTON, VA, 22201-4714, US

(21) Appl. No.: 10/407,215

(22) Filed: Apr. 7, 2003

Related U.S. Application Data
(60) Provisional application No. 60/369,804, filed on Apr. 5, 2002.

(51) Int. Cl. G06F 17/60; G01R 11/56; G06F 17/00; G01R 21/133

(52) U.S. Cl. 705/412

(57) ABSTRACT

The invention provides a system and method for remotely monitoring, measuring and billing for the thermal energy used at a plant or other customer facility. Sensors are provided for capturing the information necessary to calculate the thermal effect across heat transfer components or systems. The data from the sensors is formatted by data processing circuits for transmission to a central billing facility. The central billing facility converts the transmitted energy usage data into a customer invoice and stores the invoice in a database which can be accessed by the customer through the Internet.

### CROSS-REFERENCE TO RELATED APPLICATION

This application is based upon provisional application Serial No. 60/369,804 filed Apr. 5, 2002.

### FIELD OF THE INVENTION

The invention is directed to a system for remotely monitoring and billing for thermal energy usage. More particularly, the system involves monitoring, for example, the use of thermal energy at plant or other facilities, transmitting the energy usage data to a centralized billing facility for computing the cost of the energy used, generating a energy usage bill, and sending the energy usage bill via e-mail and/or allowing the energy usage customer to remotely access the generated energy usage bill. The customer access can be, for example, via the Internet using wireless transmission or the public switched telephone network or by using a local area network (LAN), etc.

### BACKGROUND OF THE INVENTION

The following prior art issued U.S. patents are examples of the prior art in which computer or data processing systems facilitate the transfer of information.

| U.S. Pat. No. | Inventor | Issue Date |
|---|---|---|
| 6,360,181 | GEMMELL et al. | Mar. 19, 2002 |
| 6,343,277 | GAUS et al. | Jan. 29, 2002 |
| 6,324,523 | KILLEEN, Jr. et al. | Nov. 27, 2001 |
| 6,278,983 | BALL | Aug. 21, 2001 |
| 6,237,051 | COLLINS | May 22, 2001 |
| 6,211,782 | SANDELMAN et al. | Apr. 3, 2001 |
| 6,202,056 | NUTTALL | Mar. 13, 2001 |
| 6,021,394 | TAKAHASHI | Feb. 1, 2000 |
| 5,953,682 | McCARRICK et al. | Sep. 14, 1999 |
| 5,878,401 | JOSEPH | Mar. 2, 1999 |
| 5,819,232 | SHIPMAN | Oct. 6, 1998 |

Gemmell et al., Ball, Collins, Takahashi, McCarrick et al., Joseph and Shipman are representative of prior art dealing with inventory control, resource allocation or asset tracking systems. Killeen, Jr. et al. is representative of prior art dealing with management of financial transactions. Gaus et al. is representative of prior art dealing with the management of energy transactions. Nuttal is representative of prior art dealing with the accounting for usage rights of, for example, copyrights or the like. Sandelman et al. is representative of prior art dealing with monitoring the operation of HVAC equipment and alarming the onset of fault conditions through the Internet. None of these patents discloses a system or method for remotely measuring thermal energy usage and generating an energy usage invoice.

### SUMMARY OF THE INVENTION

Thermal energy is essentially the primary ingredient in the process of adding or removing heat from industrial process gases and liquids. It is the movement of heat energy across a surface and into another medium, that then takes the thermal energy to another process where it might be needed, or it may be rejected to atmosphere, which is common in evaporative cooling systems. Thermal energy is transferred to mediums according to the physical properties of the medium, in terms of thermal conductivity, specific gravity, specific heat, and viscosity, the properties of the transferring material, typically a metal, and the turbulence and fluid velocity of each liquid.

Thermal energy can be expressed in the International Standard of British Thermal Units, or BTU's per hour. It is the amount of heat that must be added to one pound of water at sea level to raise its temperature one degree F. With this knowledge, and that of the physical properties of the liquids or gases involved, the effective heat transfer across any device can be calculated by measuring the inlet temperature, the outlet temperature and the flow rate. In the invention described herein, transducer/ sensors are strategically placed at the primary heat transfer location according to the scope of the energy usage (hereinafter THERM) contract, and the sensed values are used as part of an overall Thermal Energy Billing System Process.

The thermal energy effect, heating or cooling from one point to another, is produced by a wide variety of devices. Refrigeration systems, including those used for HVAC and industrial process cooling, boilers, heat exchangers, air and gas dryers, even radiators perform a duty around producing a thermal energy effect on the passing liquid or gas. To date, the method used by companies is the purchase or lease of the equipment required to produce the thermal effect. This represents a fixed cost, which may be amortized, but the actual demand is a variable depending on many business factors.

The issue to be solved, therefore, is the gap that exists between the capacity of the equipment and its actual use. Seasonal and production demands fluctuate, and it makes sense that the thermal energy utilized by the facility should fluctuate like any other utility. If the facility experiences a higher demand for the thermal energy effect within their facilities and processes, they should expect to pay more, and the inverse should also be true.

The inventive system allocates the actual utility costs to the energy customer in accordance with the use of equipment provided on site to produce the thermal effect. Thus, the inventive system provides significant business benefits, by combining existing microprocessor based control technologies, including programmable logic controls (PLCs) and embedded controllers, with data transmission technologies and remote computer hardware and software that provides applications accessible on the Internet. More particularly, the inventive system allows the capital cost of the equipment producing the variable thermal energy effect to be borne by another party who essentially sells the BTUs consumed to the customer as a variable utility instead of selling the equipment.

These models for utilizing thermal energy as a utility against processes and that tracks with real time demand requires the ability to produce the thermal effect on-site in the form of providing the required cooling or heating equipment, and connecting to the points of use. Because capturing the necessary data from the device is also at the point of use, the inventive system is required to capture the system variables and transfer the values to a remote computer application that can read, parse, convert and write the values to a database. The inventive system further powers Internet based applications to control the values used for the thermal calculations, the sell rate per MBTUH (Millions of BTUH), an ongoing commission rate for the sales channel, and provide on-line automated invoices, a “dashboard” showing customers, equipment providers and resellers graphical and textual information on the most recent updates regarding the operation of the equipment producing the measured thermal effect. Preferably, the database should not reside on-site for security and business reasons.

Key features and components of the inventive system include:

the capture of the specific variables that allow BTUH calculations;

the transmission of these and other variables to a remote application; and

the ability to use the variables to enable measuring and selling the thermal energy effect as an alternative to selling or leasing the capital equipment.

The invention, in the preferred exemplary embodiment, involves capturing, transferring and using the data from the point of capture to the delivery of Internet based invoices and histories of invoices and usage on a nearly real time basis. The Internet application will hereinafter be referred to as THERM, which stands for Thermal Energy Real-time Monitor. It is important to note that although the preferred embodiment of the inventive system is implemented in near real-time, meaning that the data is read and time stamped every hour, the inventive system can also support finer increments of time to become virtual. This is only marginally useful for the purposes of this thermal energy billing system, so a one hour increment has been accepted as practical and a balanced use of resources and cost.

### BRIEF DESCRIPTION OF THE DRAWINGS

FIG. 1 depicts a shell and tube heat exchanger with arranged sensors for practicing the preferred embodiment of the invention;

FIG. 2 depicts a typical water cooled chiller including sensors for practicing the preferred embodiment of the invention;

FIG. 3 depicts a closed loop system with arranged sensors for practicing the preferred embodiment of the invention;

FIG. 4 provides a schematic overview of the communication system for practicing the preferred embodiment of the invention;

FIG. 5 is schematic diagram of a portion of the equipment shown in FIG. 4; and

FIG. 6 depicts a sample energy usage invoice.

### DETAILED DESCRIPTION OF THE INVENTION

A detailed description of the invention in relation to billing for the usage of thermal energy by monitoring flow rates and temperature differentials will be presented below in four sections. It will be understood by those skilled in the art, however, that the specific thermal energy embodiment is not limiting and that the inventive system is also applicable for remote billing of thermal energy by, for example, monitoring and measuring the equipment's electricity usage and deriving thermal energy usage therefrom.

Section 1 describes the equipment layout at the energy point of use and capture of data. Section 2 describes the data transmission equipment that can be employed for transmitting energy usage data and billing information to a remote location. Section 3 describes the process from the receipt of data to the updates written to the primary application database at the remote location. Section 4 describes new computer software that powers the administrative, reseller or representative, and end users Web based “Gateways.”

Section 1

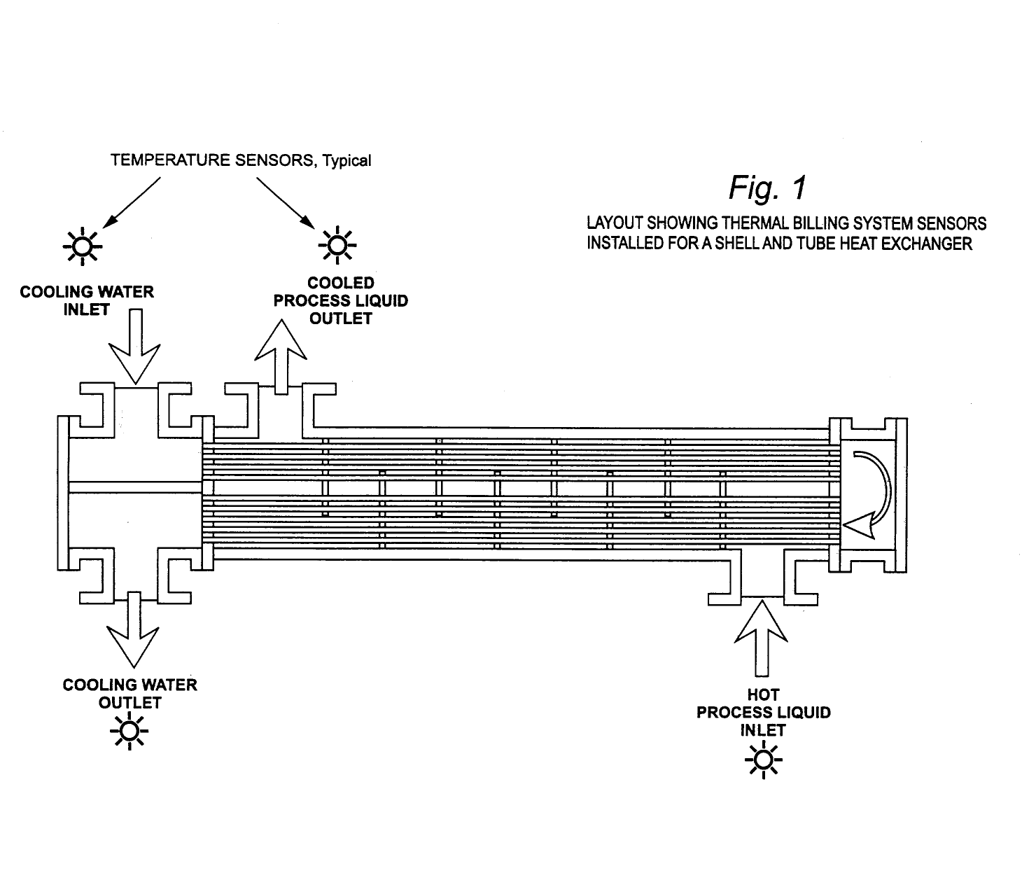

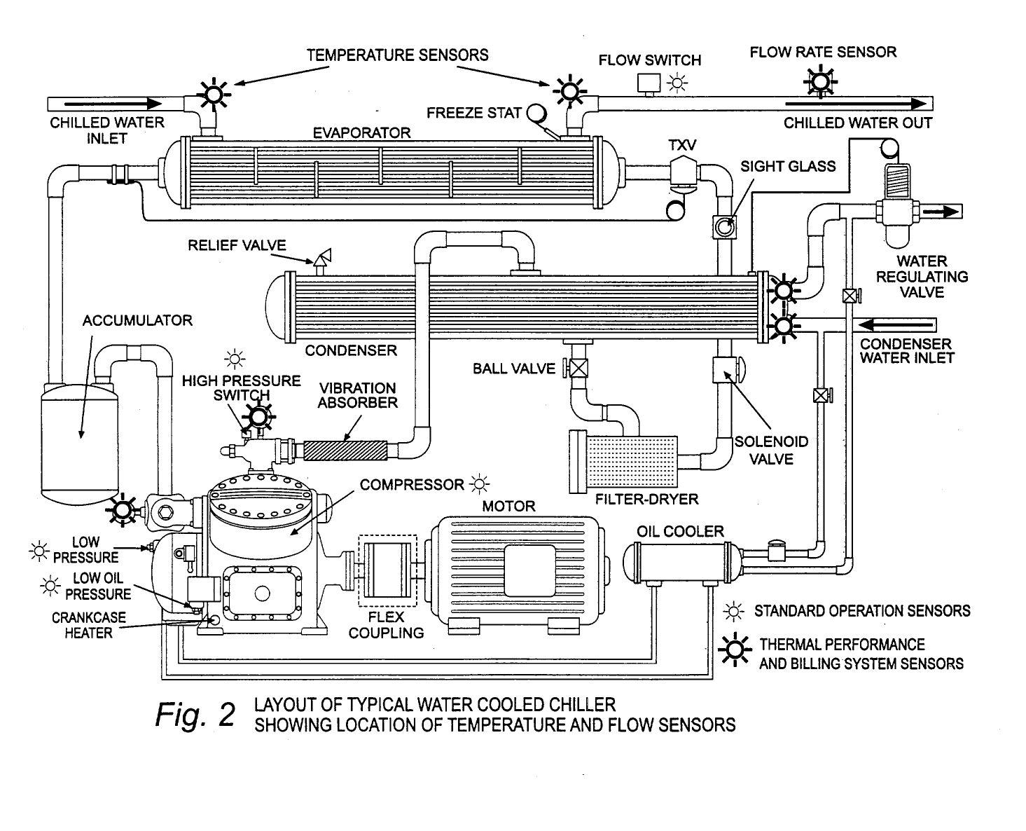

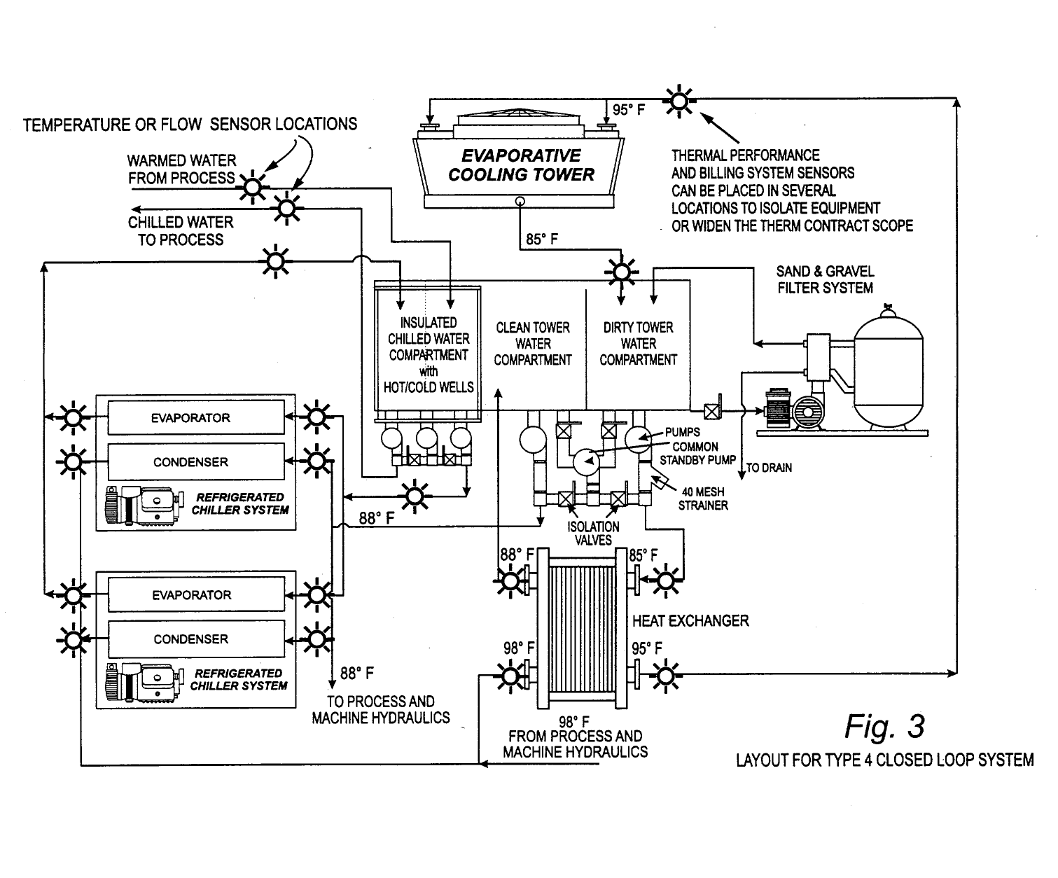

As shown in FIGS. 1-3, various thermal energy effect producing devices can have multiple “circuits,” or cascaded heat transfer locations in the scope of an overall system. In some thermal effect systems, circuits and devices and entire subsystems can be enabled, staged, and stopped. Each of these heat transfer effect circuits have at least one heat transfer location, where the device interacts with customers processes, in terms of secondary heat exchangers (shown in FIG. 1) used in the system, or condensers (shown in FIGS. 2 and 3) in the case of refrigeration, heat recovery exchangers, and atmospheric heat rejection, or as outdoor direct or evaporative cooling devices (shown in FIG. 3).

One could measure the thermal effect at any, or all of these locations within a thermal effect system, and establish a THERM contract, as described below. Therefore, essentially any heat transfer location can be made to measure the required values, and interact with the technologies described herein. For the purposes of simplicity and direct customer process contact, the preferred embodiment of the invention uses the values exposed at the primary heat transfer location at the customer process. The calculations could be combined with related heat transfer locations in the system, by breaking down their duty as part of the whole, or the thermal energy sales arrangement can be based on the overall effect produced at the point of use.

The data elements captured include those necessary to enable thermal energy usage measurements and other performance and diagnostic elements of the applications. The data elements which are necessary for the preferred embodiment of this invention are as follows:

Inlet Temperature of the customer's or end user's process liquid or gas in farenheit or centigrade degrees as measured by a sensor at the inlet of the primary point of use heat transfer device or system. This sensor may be surface mounted or inserted directly or via a bulb well into the liquid or gas stream to effect measurement;

Outlet Temperature of the customer's or end user's process liquid or gas in degrees F as measured by a sensor at the outlet of the primary point of use heat transfer device or system. This sensor may be surface mounted or inserted directly or via a bulb well into the liquid or gas stream to effect measurement; and

Flow Rate in US Gallons Per Minute measured at the Primary Exchanger. This sensor is inserted into the liquid stream.

Note: A sensing system may use multiple sensing devices to derive an average value. In a cooling or heating mode, the temperature change is from the higher value to the lower value and the database calculates the thermal effect by subtracting the inlet from the outlet, as in a cooling circuit mode. In an application where heat is added, the sensor locations at the Primary thermal effect device are reversed to obtain the correct number in the database. Users can select which mode, cooling or heating, from the Web interface regardless of the orientation of the sensors.

These same values can be captured at secondary heat transfer locations, such as condensers, manifold or other related heat exchangers. Values for the inlet and outlet pressure are captured for diagnostics, as well as the refrigerant high and low pressures, if they exist. Thus, the sensors provide operational safeties as well as providing the basis of thermal effect billing. Software will cause real time alerts to take place, notifying users of a fault condition on the equipment, such as a flow stoppage, or pressure spike. Other data elements captured are the data transmission device ID, and the time stamp of the data capture.

Section 2

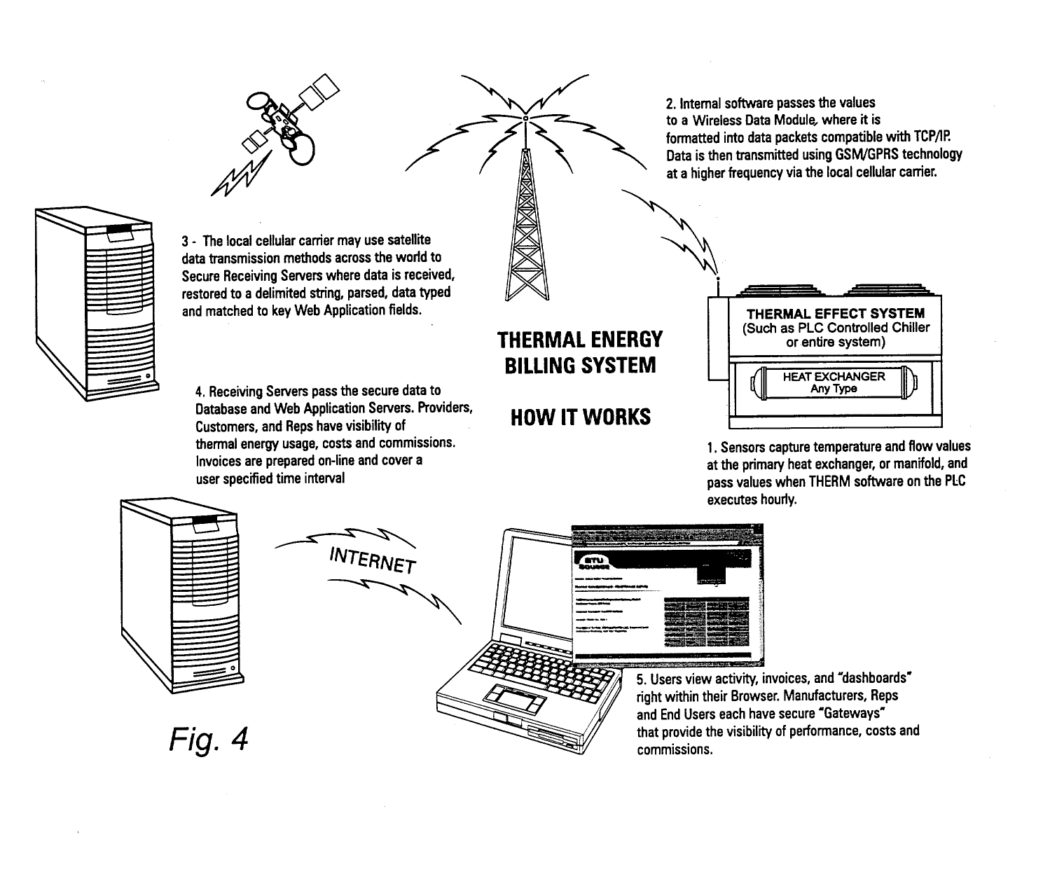

Non-volatile software, written to processing modules either within, or as an option to a Programmable Logic Controller (PLC), transmits the data on an hourly basis and retrieves the values currently present in the system from the sensors described above in smaller time increments such as, for example, every five minutes. These collected data values are passed to a communications port which is connected to a wireless data module, as shown in FIG. 4. Of course, as will be recognized by those skilled in the art, other communication systems could be utilized including, for example, the public switched telephone network, dedicated telephone lines and circuits, etc.

The system shown in FIG. 4, retrieves the data elements as a delimited string, bundles the data in packets compatible with TCP/IP protocol, and transmits the packets to a receiving IP using a local GSM/GPRS compatible cellular carriers system. The data transmission could also be enabled using paging technologies, or other hardwired means. The central issue is not the transmission method, but that the data elements are transmitted by whatever means and are adapted for transmission. In some locations, older transmission technologies may be suitable. For the preferred embodiment of this invention, wireless, TCP/IP, duplex technologies from for example, Motorola Corporation, are suitable for system compatibility in most locations.

Section 3

Once transmitted across the carriers network, and received by a dedicated modem at a predefined IP address programmed in the remote microprocessor controller, the data is processed for writing to the primary application database. Software parses the delimited string, matches each data element to its correct field, names and data types the elements for handling by the SQL Update statements according to the data types and lengths required at the application database, as shown in FIG. 4. The receiving server application database stores the activity from each PLC in its own table. A subset of data is then updated to one table in the Web Application SQL Database. The subset of data written to the Web Application Database includes keyed fields used with Web Server session variables that enable isolating secure user access to a database level by user name and password.

Section 4

The inventive system includes applications and business function modules that operate within a Web browser, and against a highly scalable SQL Server database. User access is controlled by user name and password. There are three primary modules, or “Gateways”; one each for Manufacturers, Customers and Representatives/Resellers.

The Manufacturers Gateway includes functions that create and store information that describe the THERM contract specifics, and a child table that stores values updated from the remote PLC. They are bound by a one to many relationship by THERM Item ID common to both tables, which are in turn securely bound to Companies and Orders so that users may only view their THERM contracts.

The THERM applications have many functions, including the creation of on-line, printable invoices for the THERM contract presented to the user within their Web browser. The invoice shows, for example, the amount of thermal energy used from a beginning date and an ending date, the sell rate and total thermal energy cost. This allows the customer to be billed for thermal energy consumed in any time increment agreed upon by the parties. The system is set up to e-mail invoices to recipients as well as allow the users (i.e., customers, sales representatives and THERM contract providers) to securely view and print the invoices.

The applications further include a correction factor to the MBTUH calculation to adjust for specific conditions that affect the amount of thermal energy actually transferred, such as the presence of a high glycol concentration. Otherwise the program defaults to the thermal calculations for water. Preferably, the system does not calculate the thermal effect from the (specific heat×mass×delta T) method, but instead uses the (GPM×delta T×500) method to closely approximate the heat transfer rate for water, then corrects the result according to the correction factor, which is a simple multiplier. A factor of 1 results in a water calculation, where a factor of 0.8 might approximate a certain water/glycol solution. As will be recognized by those skilled in the art, other suitable methods and formulas for calculating the thermal effect could be utilized.

The system is currently enabled for liquids. For thermal effect requirements against air or gas, the system will use the appropriate calculation method using SCFM instead of GPM. THERM contracts are also Orders, and are fully integrated into the BTU Source Order Entry System. This allows THERM customers to utilize this innovative business model while working within the constraints of regular business processes and views within the applications.

The THERM contract is captured by the THERM Header table. There are Create, Update and Delete functions for the THERM Header table. It captures information such as contract term, the PLC ID and its access address, the receiving IP address, the cellular carrier access numbers, the sell rate in MBTUH, the ongoing commission rate per MBTUH for any reseller, the equipment descriptions, serial numbers, internal and external contacts, valuations of the equipment and equipment finance information. It also establishes the ID that links the PLC data in the THERM Detail table to the correct THERM contract.

Users of the Web applications may view THERM contract information, invoices, history, payments against invoice, and a “dashboard” that views the most recent PLC updates for the most recent time stamps. The dashboard includes six line graphs that track with the inlet and outlet temperatures, the flow rates and pressures of various points in the system. These dashboards can also be viewed across a user specified date range, to allow viewing across several months of activity. The Web Applications are built to provide these technologies to any subscriber company.

The preferred embodiment of the inventive system uses hardware and software to transmit variables captured by a micro-controller, or PLC, using specially placed sensors, to remote servers capable of using the data to derive Internet billing of thermal energy. The billing and sales commission delivery process therefore involves the PLC and associated software as well as the use of a data transmission device, a data carrier, receiving software, and database driven Web applications (see FIG. 4).

In practice, the preferred embodiment of the inventive system includes a PLC and associated software, a communications port adapter (RS232), a modem; local data carrier service, and suitable connection and interfacing to Web based technology. These features and components of the inventive system can be provided by OEMs or users, and the components and/or software can be leased or purchased by any one or all parties to the contractual arrangement.

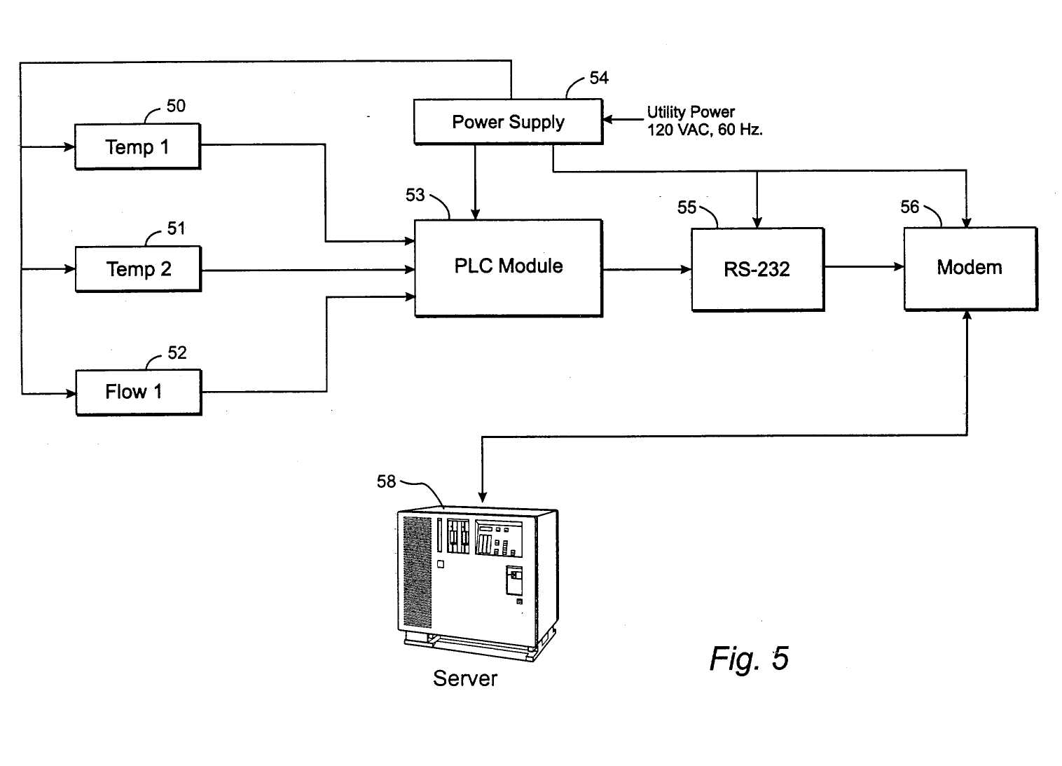

FIG. 5 shows in block diagram the sensor/PLC assembly components of the FIG. 4 exemplary embodiment. As shown in FIG. 5, temperature transducers 50 and 51 measure inlet and outlet temperatures of chilled water, refrigerant or the like and output a corresponding number of electrical signal pulses. Flow rate transducer 52 measures the flow rate of the chilled water, refrigerant or the like and outputs a corresponding number of electrical signal pulses. The outputs from transducers 50-52 are input to PLC Module 53 which outputs processed data signals through an RS-232 interface 55 to Modem 56. A power supply 54 supplies power to transducers 50-52, PLC Module 53, Interface 55 and Modem 56.

In the preferred embodiment, PLC Module 53 reads (i.e., detects and counts) raw incremental pulses received from the transducers 50-52 every five minutes and stores the values in data registers. On an hourly basis, PLC Module 53 packs and transmits the stored data through Interface 55 and Modem 56 to Server 57. If analog telephone lines are used to transmit the data then a Hayes Compatible modem is utilized. If wireless transmission is employed, then Modem 56 can be, for example, a Motorola G18 GSM/GPRS wireless modem. The data is transmitted using standard TCP/IP protocol.

Server 57 receives the transmitted data and uses the data to calculate the thermal energy usage invoice. The Server 57 then e-mails the invoice to the end user or customer and/or provides differing levels of access to its database storing the invoice as described above. In the preferred embodiment, temperature and flow rate transducers are used to obtain the data necessary to compute thermal energy usage. The invention is not limited to this embodiment, however, and can alternatively monitor and sense other parameters from which thermal energy usage can be calculated. For example, a measure of the electrical power needed to drive the thermal equipment (i.e., chiller, compressor, etc.) together with the equipment's efficiency rating can be used in computing the thermal energy usage.

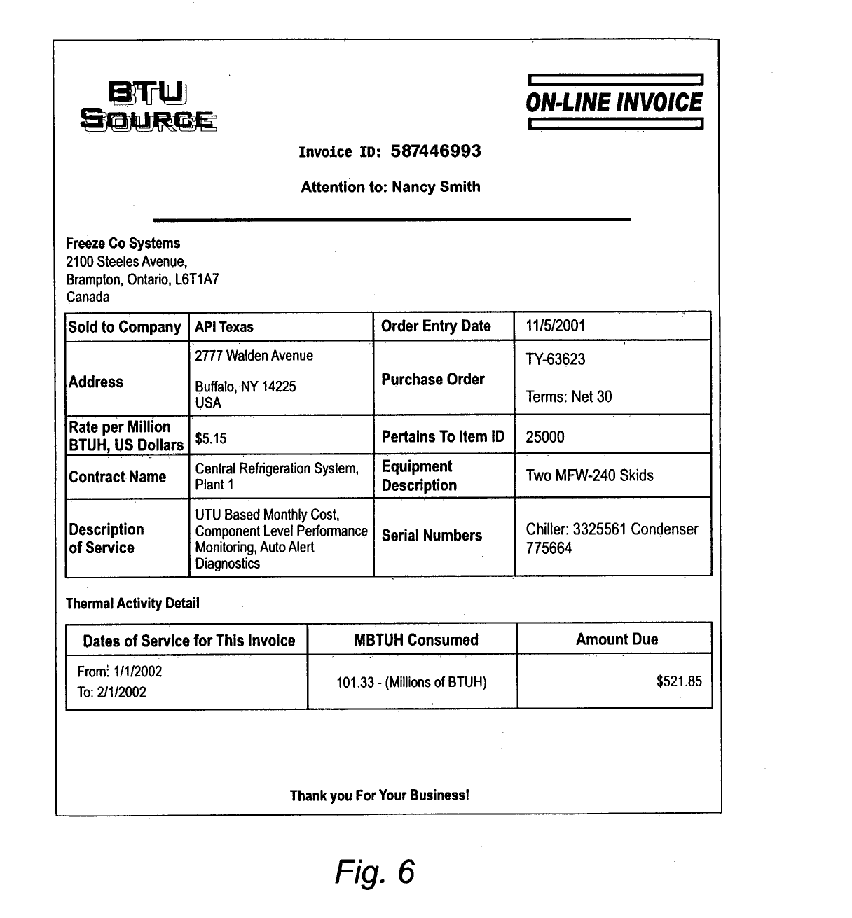

FIG. 6 shows an exemplary energy usage invoice which can be sent by e-mail to a customer or end user or accessed by the customer or end user over the Internet. The invoice identifies the customer's location and energy usage premises and other administrative information. The invoice clearly sets forth the energy rate, BTU's consumed and cost of the energy consumed.

While the invention has been described in connection with what is presently considered to be the preferred exemplary embodiment, it is to be understood that the invention is not to be limited to the disclosed embodiment, but on the contrary, is intended to cover all modifications and equivalent arrangements included within the spirit and scope of the appended claims.

What is claimed:

1. A system for monitoring, measuring and billing thermal energy usage at a remote location, said system comprising:
a plurality of sensors for measuring thermal energy usage and outputting data indicative of the measured thermal energy usage at the remote location;
energy usage data processing circuits for receiving the data output from said plurality of sensors and formatting the data for transmission to a central billing location;
data transmission equipment for receiving the formatted data from said data processing circuits and transmitting the formatted data to the central billing location; and
a data collection server located at the central billing location for receiving the transmitted data and converting the transmitted data into an invoice reflective of the thermal energy usage.

2. A system as claimed in claim 1, said data collection server storing said invoice in a database.

3. A system as claimed in claim 2, wherein a customer, associated with the energy usage and said invoice, is allowed to access said invoice stored in said database.

4. A system as claimed in claim 3, wherein the customer access is provided through an Internet connection.

5. A system as claimed in claim 1, said data being transmitted via wireless transmission.

6. A system as claimed in claim 5, said data collection server storing said invoice in a database.

7. A system as claimed in claim 6, wherein a customer, associated with the energy usage and said invoice, is allowed to access said invoice stored in said database.

8. A system as claimed in claim 7, wherein the customer access is provided through an Internet connection.

9. A method for monitoring, measuring and billing thermal energy usage at a remote location, said method comprising:
measuring thermal energy usage at the remote location and outputting data indicative of the measured thermal energy usage;
processing the data indicative of the measured thermal energy usage and formatting the data for transmission to a central billing location;
transmitting the formatted data to the central billing location; and
converting the transmitted data received at the central billing location into an invoice reflective of the measure thermal energy usage.

10. A method as claimed in claim 9, further comprising storing said invoice in a database.

11. A method as claimed in claim 10, further comprising a customer, associated with the thermal energy usage and said invoice, accessing said invoice stored in said database.

12. A method as claimed in claim 11, said customer access being provided through an Internet connection.

13. A method as claimed in claim 9, said formatted data being transmitted via wireless broadcast.

14. A method as claimed in claim 13, further comprising storing said invoice in a database.

15. A method as claimed in claim 14, further comprising a customer associated with the energy usage and associated said invoice accessing said invoice stored in said database.

16. A method as claimed in claim 15, said customer access being provided through an Internet connection.

17. A billing system for measuring thermal energy usage and electronically billing a customer for the thermal energy usage, said billing system comprising:
means for measuring thermal energy usage and outputting data indicative of the measured thermal energy usage at a remote customer location;
data processing means for receiving the data output from said measuring means and formatting the data for transmission to a centralized billing location;
data transmission means for receiving the formatted data from said data processing means and transmitting the formatted data to the centralized billing location; and
data collection means located at the centralized billing location for receiving the transmitted data and converting the transmitted data into a customer invoice reflective of the measured thermal energy usage, said customer invoice being electronically stored by said data collection means.

18. A billing system as claimed in claim 17, wherein the customer, associated with the measured thermal energy usage and said customer invoice, can access said customer invoice stored by said data collection means.

19. A billing system as claimed in claim 18, wherein customer access is provided through an Internet connection.

20. A billing system as claimed in claim 19, wherein said means for measuring energy usage measures thermal energy.
